(19) United States
(12) Patent Application Publication
(10) Pub. No.: US 2026/0262326 A1
(43) Pub. Date: Sep. 3, 2026

(54) SOLAR CELL AND METHOD OF MAKING THE SAME

(71) Applicant: HAMAD BIN KHALIFA UNIVERSITY(HBKU), Doha (QA)

(72) Inventors: Brahim Aïssa, Doha (QA); Adnan Ali, Doha (QA)

(21) Appl. No.: 18/870,827

(22) PCT Filed: Jun. 1, 2023
(86) PCT No.: PCT/QA2023/050009

§ 371 Date: Dec. 2, 2024

Related U.S. Application Data
(60) Provisional application No. 63/365,747, filed on Jun. 2, 2022.

(51) Int. Cl. H10F 77/14; B41M 3/00; B41M 5/00

(52) U.S. Cl. CPC H10F 77/1437; B41M 3/006; B41M 3/008; B41M 5/0047

(57) ABSTRACT

A solar cell device and a method of making the same are provided. The method of making a solar cell device includes inkjet printing microdots on a substrate, dewetting the microdots to obtain nanoparticles at positions where the plurality of microdots were printed, depositing a thin film on the nanoparticles, and dewetting the thin film to form nanorods and nanoparticles on the same surface, wherein the positions of the nanoparticles on the surface of the substrate serve as seeds for the formation of the nanords.

### CROSS-REFERENCES TO RELATED APPLICATIONS

The present disclosure claims priority to U.S. Provisional Patent Application 63/365,747 titled “Solar Cell and Method of Making the Same” having a filing date of Jun. 2, 2022, the entirety of which is incorporated herein.

### BACKGROUND

Due to their shape anisotropy (physical properties), nanorods are an attractive component to be studied and an ideal candidate for many plasmonic applications. Due to the high aspect ratio of nanorods, the excitation of surface plasmons increases, compared to the excitation seen in spherical-shaped particles. Consequently, the dipole moment strength increases within a nanoparticle due to the increase in excitation of surface plasmons. Therefore, an increase of surface plasmons leads to an enhancement of the electrical field in nanorods as compared spherical particles. Consequently, having nanorods and nanoparticles on the same surface may assist in utilizing the light spectrum more efficiently, for example resulting in more efficient light absorption by solar cells.

Various techniques are used for synthesizing nanorods, either via physical or chemical methods, known as bottom-up or top-down techniques, and are comprehensively: thermal hydrolysis; hydrothermal route; sol-gel; vapor condensation; spray pyrolysis; pulse laser decomposition; thermal evaporation; pulse combustion-spray pyrolysis; electro-mechanical; flame spray plasma; microwave plasma; low energy beam deposition; ball-milling; chemical vapor deposition; chemical reduction; co-precipitation; hybrid wet chemical route; physical evaporation; electrophoretic deposition; radio frequency (RF) magnetron sputtering; vapor deposition; metal assisted growth; template assisted routes; metal-assisted growth; seed-based growth; and simple chemical etching. Typically, nanorods are prepared by controlling the nucleation growth.

All these synthesis techniques are expensive due to requiring a vacuum, expensive tools to fabricate, or involve many fabrication steps and safety issues. Accordingly, a need exists for a cost-effective and efficient method of synthesizing nanorods on the same surface of nanoparticles.

### SUMMARY

According to one non-limiting aspect of the present disclosure, an example embodiment of a method of making a solar cell device is provided.

In light of the present disclosure, and without limiting the scope of the disclosure in any way, in an aspect of the present disclosure, which may be combined with any other aspect listed herein unless specified otherwise, a method of making a solar cell is provided.

In an aspect of the present disclosure, which may be combined with any other aspect listed herein unless specified otherwise, the method may include inkjet printing microdots on a substrate, dewetting the microdots to obtain nanoparticles at positions where the plurality of microdots were printed, depositing a thin film on the nanoparticles, and dewetting the thin film to form nanorods, wherein the positions of the nanoparticles serve as seeds for formation of the nanorods. In other words, the nanoparticle positions beneath may be utilized as seeds or nucleates for nanorod formation.

In another aspect of the present disclosure, which may be combined with any other aspect listed herein unless specified otherwise, a solar cell device is provided, which may comprise a substrate and a plurality of microdots inkjet printed in a pattern on a surface of the substrate, wherein the plurality of microdots is configured to form nanoparticles, in response to dewetting, and to form nanorods, in response to depositing a thin film on the nanoparticles, and dewetting the thin film.

Additional features and advantages are described herein, and will be apparent from the following Detailed Description and the figures.

### BRIEF DESCRIPTION OF THE FIGURES

Features and advantages of the present disclosure, including a solar cell device and a method of making the same, described herein may be better understood by reference to the accompanying drawings in which:

FIGS. 1a-d illustrates an example fabrication methodology of the present disclosure.

FIG. 2 illustrates a variety of example patterns in which the microdots may be deposited and there general appearance pre- and post-dewetting.

FIG. 3 illustrates a flowchart depicting an example solar cell fabrication method according to an aspect of the present disclosure.

FIGS. 4a and 4b illustrate a reflectance spectra and I/V characteristics, respectively, of a solar cell configuration according to an aspect of the present disclosure.

FIG. 5 illustrates scanning electron microscope (SEM) images and analysis of inkjet-printed Ag microdots and nanoparticle chunks after dewetting for acting as nucleating sites for nanorod formation according to an embodiment of the present disclosure.

FIG. 6 illustrates a chart depicting the various technology fields of application for aspects of the present disclosure

The reader will appreciate the foregoing details, as well as others, upon considering the following detailed description of certain non-limiting embodiments of the present disclosure.

### DETAILED DESCRIPTION

The present disclosure is generally related to a solar cell device and a method of making the same.

In the present disclosure, a method of making a solar cell device as further disclosed in detail as a cost effective fabrication method requiring no vacuum or lithography. It is a one-step direct-fabrication approach for both random and regular metasurface/plasmonic structure/network and array, achieved directly on a given substrate. In addition, it gives the freedom of designing the pattern array directly in printing via, for example, a control signal.

According to an embodiment of the present disclosure, there is provided a solar cell device. One feature of the solar cell device is that it comprises accurately, uniformly, and equidistantly-deposited metasurface and plasmonic structures on a surface of a substrate of the solar cell device. For example, nanorods chunks embedded within a randomly distributed nanoparticles arrays are fabricated directly onto the substrate to trigger/enhance the plasmonic effect for enhancing light harvesting in solar cell. Unlike the usually employed spherical-shaped noble metal nanomaterials (mainly Au and Ag), the geometrically anisotropic rod-like structures are likely to present anisotropic conductivity to electron migration between the transverse and longitudinal directions. The transverse resonance absorption peak of rod-like structure can promote the direct employment of the visible light. Longitudinally, it can, for example, (i) boost the optical scattering, (ii) increase the optical path length, and (iii) promote the possibility of photon harvesting, especially for the near-infrared light (NIR).

Therefore, it is expected that the localized surface plasmon resonance effect of metal nanorods can effectively utilize photon energy chiefly through both far-field scattering and near-field improvements, thus promoting the PV performance of solar cell devices. In sum, combination of both (i) precisely controlled spaced nanorods and (ii) randomly oriented nanoparticles on the same surface is unique and provides dual plasmonic effect for efficient light harvesting in order to utilize a broader portion of the light spectrum.

According to another embodiment of the present disclosure, there is provided a solar cell device by an inkjet printed method. Inkjet printing is a cost-effective non-vacuum and lithography-free fabrication process which may be applied to achieve a dual-plasmonic nanostructure, i.e. precisely controlled and equidistantly-spaced nanaorods chunks and dewetted nanoparticles fabrication.

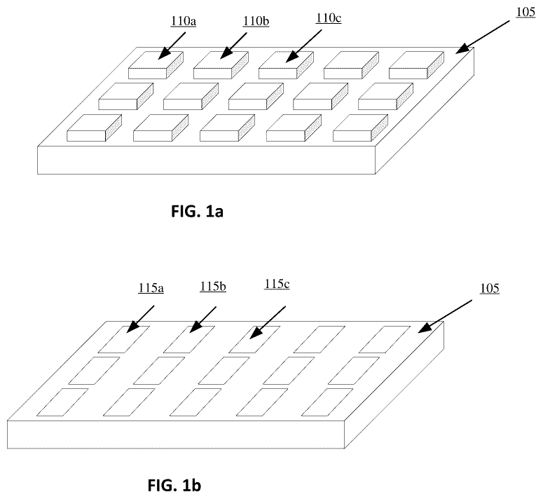

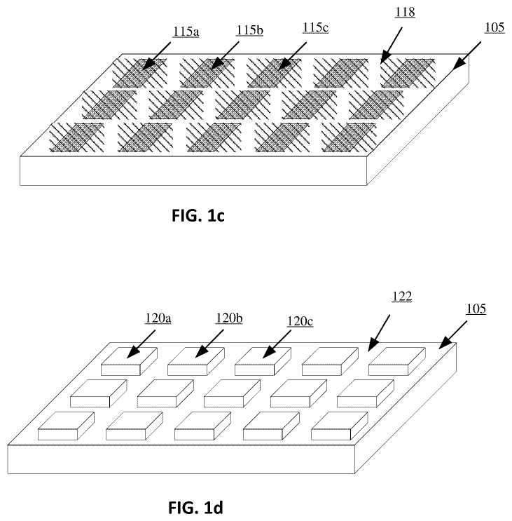

FIGS. 1a-d illustrate a method of fabricating a solar cell device. As depicted in FIG. 1a, a plurality of microdots, e.g. microdots 110a-c, may be deposited on a substrate 105. For example, an inkjet printer may be used print to deposit square-shaped microdots, e.g. microdots 110a-c, on a substrate 105. The inkjet printer may utilize inks made of silver or gold and that contain a high solid content, such as in the range of 70-80%. The ink may also not require heating in order to be deposited on the substrate, allowing the example fabrication method of the present disclosure compatible more inks. Also, the substrate may be a flexible substrate. Additionally, the inkjet printer may deposit the microdots in such a manner that the microdots of the plurality of microdots, e.g. microdots 110a-c, are positioned equidistantly from each other on the surface of the substrate 105. The microdots may have a circular shape, or as depicted in FIG. 1a, a square shape.

In an embodiment of the present disclosure, the plurality of microdots may be deposited on the substrate 105 in response to a control signal. The control signal may be a signal from a controller internal or external to the inkjet printer, which controls the printing process, i.e. the depositing of microdots of ink on the substrate. This control signal may define the shape of the microdots as well as the pattern formed by the plurality of microdots As depicted in FIG. 1b, the microdots of the plurality of microdots are dewetted in order to obtain nanoparticles formed on the substrate 105. The nanoparticles, e.g. nanoparticles 115a-c, form as chunks from the microdots on the substrate 105 after dewetting.

As depicted in FIG. 1c, a thin film 118 is deposited on top of the formed nanoparticle chunks, e.g. nanoparticles 115a-c, on the substrate 105. This thin film 118 may be deposited by an inkjet printer, which may be the same inkjet printer as the one which deposited microdots on the substrate 105.

As depicted in FIG. 1d, the thin film 118 is dewetted resulting in nanorods forming on the sites of the nanoparticle chunks. The positions of the nanoparticles beneath the thin film 118 operate as seeds or nucleates, for the formation of the nanorods at these positions. In other words, the thin film is dewetted to form nanorods, while utilizing the beneath nanoparticles positions as seeds/nucleates. For example, nanorods 120a-c formed on the site of nanoparticle chunks 115a-c. Additionally, the thin film 118 covering areas of the surface of the substrate 105 not including microdots is dewetted to form randomly oriented nanoparticles, e.g. nanoparticles present on the substate at 122. The resulting substrate is one that has both nanoparticles, e.g. nanoparticles 122, and nanorods, e.g. nanorods 120a-c, on the same surface, which may be implemented as a solar cell to allow for high efficiency light absorption. Nanostructure-induced light harvesting in solar cells offers a very effective solution to realize high-performance PVs, via the effects of antireflection, plasmonic scattering, surface plasmon polarization, localized surface plasmon resonance and optical cavity.

Due to their shape anisotropy (physical properties), the light harvesting ability of the nanorods is enhanced as compared to spherical particles. This is due to the increase of the aspect ratio of the nanoparticle which leads to the increase of excitation of surface plasmons in the nanoparticles. Particularly, the strength of the dipole moment is increased within a nanoparticle due to incrementing of surface plasmons. Therefore, an increase of surface plasmons leads to the enhancement of electrical field in the nanorods as compared to spherical particles.

Thus, combination of both (i) precisely controlled and spaced nanorods and (ii) randomly oriented nanoparticles on the same surface is unique and provide dual plasmonic effect for efficient light harvesting and absorption, which may be utilized, for example in the construction of a solar device.

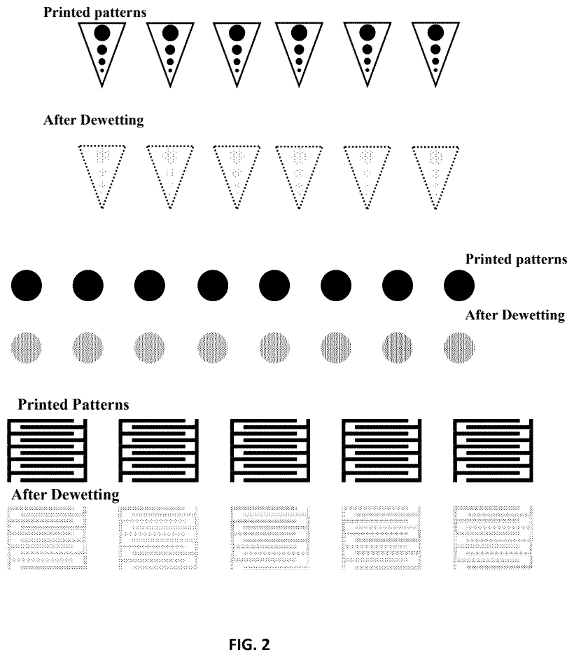

FIG. 2 illustrates a variety of example patterns in which the plurality of microdots may be deposited on the substrate. As shown, by utilizing an inkjet printing method to deposit the microdots on the substrate 105, the spacing of the individual microdots may be precisely controlled. This ensures that the microdots may be positioned equidistantly from one another, such that the nanoparticles and nanorods form in a manner that allows for the proper formation of the randomly-oriented nanoparticles on the dewetted surface of the substrate.

FIG. 3 illustrates a flowchart of an example method of a fabrication process of a solar cell device. Although the example method 300 is described with reference to the flowchart illustrated in FIG. 3, it will be appreciated that many other methods of performing the acts associated with the method 300 may be used. For example, the order of some of the blocks may be changed, certain blocks may be combined with other blocks, blocks may be repeated, and some of the blocks described are optional. The method 300 may be performed by processing logic that may comprise hardware (circuitry, dedicated logic, etc.), software, or a combination of both.

In example method 300, an inkjet printer is utilized to print microdots, equidistant from one another, directly on the surface of a substrate (block 305). For example, the inkjet printer includes a controller that interacts with a user interface, wherein a user may input instructions which the controller translates into a control signal which is transmitted to the inkjet printer. The printer will deposit the microdots on the surface of the substrate according to the instructions in the control signal. This may be implemented through a software program with a user interface which communicates with the inkjet printer.

Example method 300 also includes dewetting the printed microdots such that nanoparticles in the form of nano-nucleate chunks for at the sites where the microdots were printed (block 310). Example method 300 further includes depositing a thin film over the nanoparticles formed on the substrate surface (315). For example, the inkjet printer may be used to deposit the thin film which covers the formed nanoparticles. Example method 300 continues to include dewetting the deposited thin film such that nanorods form at the sites where the nanoparticles had formed. The remained of the thin film not covering the nanoparticles is also dewetted which leads to the formation of randomly-oriented nanoparticles on the surface of the substrate such that the substrate contains both nanoparticles and nanorods on the same surface of the substrate. This substrate may then be deployed in a solar cell device, where its light absorption abilities provide improvements on traditional solar cell technologies.

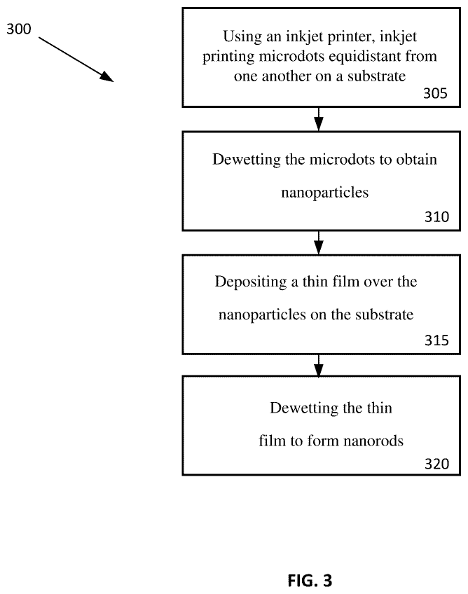

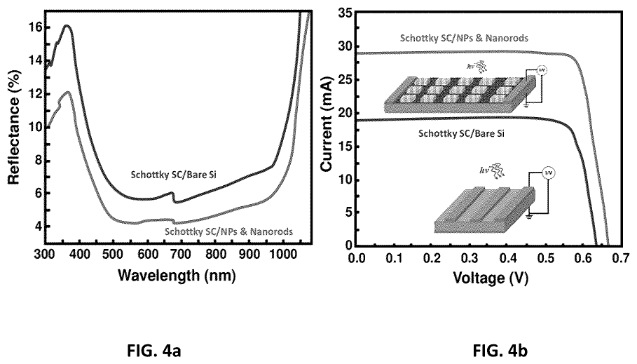

FIG. 4a depicts a reflectance spectra of a solar cell prepared according to an aspect of the present disclosure. FIG. 4a shows the reflectance of Schottky solar cell using bare Si vs. using a substrate with both nanoparticles and nanorods according to the present disclosure, such as using an Ag ink to form the nanoparticles and nanorods. It can be seen from FIG. 4a that a solar cell constructed using a fabrication process according to the present disclosure displays a lower reflectance of light across a wide spectrum compared to traditional solar cells.

FIG. 4b depicts the current-voltage characteristics of a solar cell prepared according to an aspect of the present disclosure. FIG. 4b shows the current flowing in a Schottky solar cell using bare Si vs. using a substrate with both nanoparticles and nanorods according to the present disclosure, such as using an Ag ink to form the nanoparticles and nanorods. It can be seen from FIG. 4b that a solar cell constructed using a fabrication process according to the present disclosure produces a high level of current draw across the different operating voltages.

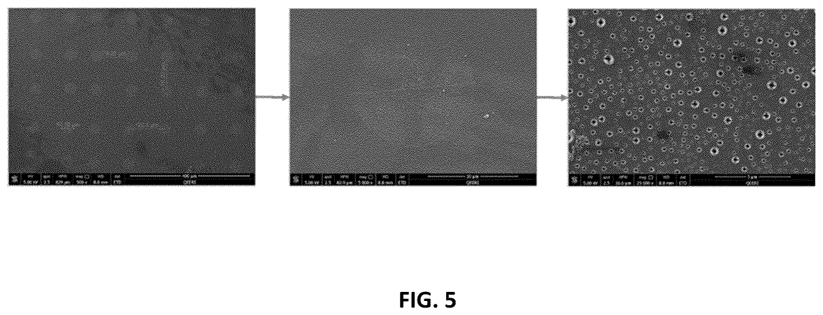

FIG. 5 illustrates SEM images and analysis of inkjet printed Ag microdots and nanoparticles chunks post-dewetting for acting as nucleating sites for nanorods formation according to an embodiment of the present disclosure.

Here, non-vacuum lithography free inkjet printing approach coupled with dewetting for dual plasmonics nanostructure (i.e. nanoparticles and nanorods) in differently configured arrays is proposed for enhancement of solar cell efficiency. Equidistantly spaced controlled nanorod chunks can systematically harvest the light more efficiently compared to randomly grown nanorods. This unique approach is markedly enhances the solar cell efficiency in a very cost effective way. This approach might be universal and could be applied in other fields as well, including photochemistry, optics, analytical chemistry, biomedicines, electronics, etc.

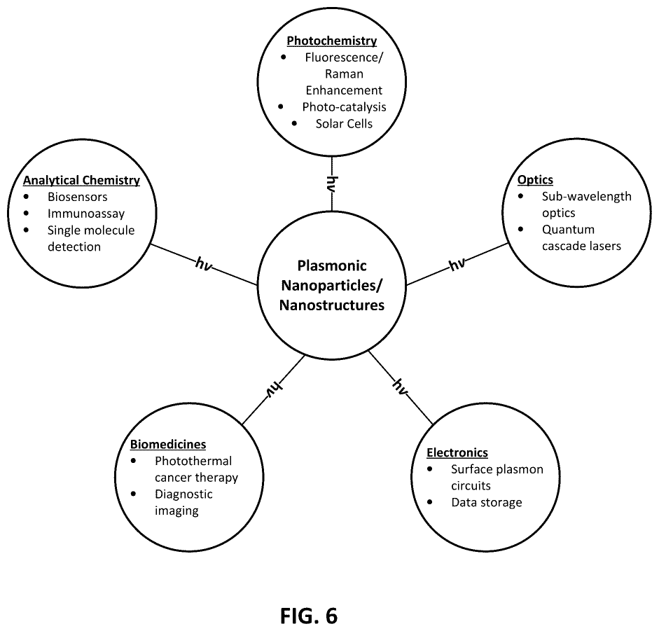

FIG. 6 depicts a chart displaying several fields of application for plasmonics and the present disclosure. Plasmonic nanoparticles and metamaterials have wide range of applications ranging from energy to health fields. The only limit is the imagination behind. More particularly, the surface plasmon resonance bands of metal nanoparticles can be tuned from visible to near infrared region by varying the shape of the metal nanoparticles. It is a rapidly growing field of research that opens up multiple opportunities toward commercial applications.

Advantages of the solar cell device and the method of making the same according to an embodiment of the present disclosure include, but are not limited to, (i) cost-effective, non-vacuum and lithography free fabrication process to grow random and ordered array/network of plasmonics and metamaterial nanostructures directly on substrate, for light harvesting to enhance solar cell efficiency; (ii) cost-effective materials (with an innovative configuration); easy to scale-up; multiple functionalities in terms of light management; and (iii) large potential applications range.

Further applications of the fabrication technology as disclosed in the present disclosure include, but are not limited to, (i) photovoltaics, (ii) solar heaters, (iii) data storage, (iv) electronics and optics, (v) sensing, (vi) telecommunications and (vii) water splitting.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A method of making a solar cell, comprising:
inkjet printing a plurality microdots onto the surface of a substrate,
dewetting the microdots to obtain nanoparticles on the surface of the substrate at positions where the plurality of microdots were printed,
depositing a thin film over the surface of the substrate, including the nanoparticles, and
dewetting the thin film to form nanorods, wherein the positions of the nanoparticles on the surface of the substrate serve as seeds for formation the nanorods.

2. The method of claim 1, wherein the microdots have an equal distance from each other.

3. The method of claim 1, wherein the microdots have a square or circular shape.

4. The method of claim 1, wherein an inkjet printer is used to deposit the thin film.

5. The method of claim 1, wherein the inkjet printing microdots on a substrate is in response to receiving a control signal.

6. The method of claim 5, wherein microdots have a shape defined by the control signal.

7. The method of claim 1, wherein the microdots are printed using an ink with a sold content between 70% and 80%.

8. The method of claim 1, wherein the substrate is a flexible substrate.

9. The method of claim 1, wherein ink used in the inkjet printing does not require heating to be deposited.

10. A solar cell device comprising:
a substrate;
a plurality of microdots inkjet printed in a pattern on a surface the substrate, wherein the plurality of microdots is configured to form nanoparticles, in response to dewetting, and to form nanorods, in response to depositing a thin film on the nanoparticles, and dewetting the thin film.

11. The device of claim 10, wherein the microdots of the plurality of microdots are positioned equidistantly from each other on the surface of the substrate.

12. The device of claim 10, wherein the microdots of the plurality of microdots have a square or circular shape.

13. The device of claim 10, wherein an inkjet printer is used to deposit the thin film.

14. The device of claim 10, wherein a control module is configured to transmit a control signal defining at least one of the shape of the microdots and the pattern of the plurality of microdots.

15. The device of claim 10, wherein the microdots are printed using an ink with a sold content between 70% and 80%.

16. The device of claim 10, wherein the substrate is a flexible substrate.

17. The device of claim 10, wherein ink used in the inkjet printing does not require heating in order to be deposited on the substrate.
